(19) United States
(12) Patent Application Publication
(10) Pub. No.: US 2022/0270900 A1
(43) Pub. Date: Aug. 25, 2022

(54) WAFER TEMPERATURE ADJUSTING DEVICE, WAFER PROCESSING APPARATUS, AND WAFER TEMPERATURE ADJUSTING METHOD

(71) Applicant: SUMITOMO HEAVY INDUSTRIES ION TECHNOLOGY CO., LTD., Tokyo (JP)

(72) Inventor: Sadao Hashiguchi, Ehime (JP)

(21) Appl. No.: 17/677,435

(22) Filed: Feb. 22, 2022

(30) Foreign Application Priority Data
Feb. 24, 2021 (JP) 2021-027143

(51) Int. Cl. H01L 21/67; C23C 16/455; H01L 21/687

(52) U.S. Cl. CPC H01L 21/67248; C23C 16/45563; C23C 16/45557; H01L 21/68742; H01L 21/67201

(57) ABSTRACT

A wafer temperature adjusting device includes an upper surface, a wafer support mechanism that supports a wafer above the upper surface in a state where a distance between the upper surface and the wafer is maintained within a predetermined range and a first space between the upper surface and the wafer communicates with a second space above the wafer, a stage that adjusts a temperature of the upper surface, and a gas supply unit that supplies a heat transfer gas to the first space and the second space.

### RELATED APPLICATIONS

The content of Japanese Patent Application No. 2021-027143, on the basis of which priority benefits are claimed in an accompanying application data sheet, is in its entirety incorporated herein by reference.

### BACKGROUND

### Technical Field

Certain embodiments of the present invention relates to a device and a method that adjusts wafer temperature.

### Description of Related Art

In a case where a wafer is processed in a semiconductor manufacturing process, the wafer may be heated or cooled in at least one of timings before, during, and after the processing. For example, there is a method in which a heater is disposed facing a front surface or a back surface of the wafer and the wafer is heated by thermal radiation from a heater. In addition, an electrostatic attraction mechanism that adjusts the temperature of the wafer by supplying a heat exchange gas to the back surface of the wafer in a state where the wafer is held to an electrostatic chuck is known the related art).

### SUMMARY

According to an embodiment of the present invention, there is provided a wafer temperature adjusting device including an upper surface; a wafer support mechanism that supports the wafer above the upper surface in a state where a distance between the upper surface and the wafer is maintained within a predetermined range and a first space between the upper surface and the wafer communicates with a second space above the wafer; a stage that adjusts a temperature of the upper surface; and a gas supply unit that supplies a heat transfer gas to the first space and the second space.

Another embodiment of the present invention is a wafer processing apparatus. This apparatus includes a vacuum processing chamber in which a process on the wafer is performed; the wafer temperature adjusting device of the above embodiment, which adjusts the temperature of the wafer in at least one of timings before and after the process in the vacuum processing chamber; a temperature adjusting chamber where the wafer temperature adjusting device is provided; a gate valve capable of sealing between the vacuum processing chamber and the temperature adjusting chamber; and a an evacuation device that reduces a pressure in the temperature adjusting chamber.

Still another embodiment of the present invention is a wafer temperature adjusting method. This method includes adjusting a temperature of an upper surface; supporting the wafer above the upper surface in a state where a distance between the upper surface and the wafer is maintained within a predetermined range and a first space between the upper surface and the wafer communicates with a second space above the wafer; and supplying a heat transfer gas to the first space and the second space.

In addition, optional combinations of the above constituent elements and those obtained by substituting the constituent elements or expressions of the present invention with each other among methods, devices, systems, and the like are also effective as embodiments of the present invention.

According to the embodiments of the present invention, the temperature of the wafer can be uniformly and quickly adjusted.

### BRIEF DESCRIPTION OF THE DRAWINGS

FIG. 1 is a sectional view showing a schematic configuration of a wafer temperature adjusting device according to an embodiment of the present invention.

FIG. 2 is a top view showing a schematic configuration of the wafer temperature adjusting device of FIG. 1.

FIG. 3 is a graph schematically showing adjustment times of wafer temperature.

FIG. 4 is a top view showing a schematic configuration of an ion implanter according to the embodiment of the present invention.

FIG. 5 is a side view showing a schematic configuration of the ion implanter of FIG. 4.

FIG. 6 is a top view showing a schematic configuration of a wafer transport device according to the embodiment of the present invention.

FIG. 7 is a flowchart showing an example of an operation of the wafer transport device.

FIG. 8 is a sectional view showing a schematic configuration of a wafer temperature adjusting device according to another embodiment of the present invention.

FIG. 9 is a sectional view showing a schematic configuration of a wafer temperature adjusting device according to still another embodiment of the present invention.

### DETAILED DESCRIPTION

In a case where the thermal radiation is utilized to heat the wafer, there is a concern that it takes a long time to heat the wafer because the thermal response of the radiation system is low, and it is difficult to uniformly heat the entire surface of the wafer. Additionally, in a case where the heat exchange gas is supplied to the back surface of the wafer in a state where the wafer is held by the electrostatic chuck, the wafer may bounce on the electrostatic chuck due to the pressure of the heat exchange gas present on the back surface of the wafer when the attractive force of the electrostatic chuck is reduced. In order to prevent the bouncing of the wafer, it is necessary to sufficiently exhaust the gas on the back surface of the wafer before all the attractive force is released, and it takes substantial time to exhaust the gas. When it takes substantial time to adjust the temperature of the wafer, the productivity of the semiconductor manufacturing process is lowered.

It is desirable to provide a technique for uniformly and quickly adjusting the temperature of the wafer.

Hereinafter, embodiments for carrying out the present invention will be described in detail with reference to the drawings. In addition, in the description of the drawings, the same elements will be designated by the same reference numerals, and the duplicated description thereof will be appropriately omitted. Additionally, the configuration to be described below is merely exemplary and does not limit the scope of the present invention at all.

An outline will be given before an embodiment is described in detail. The present embodiment is a wafer temperature adjusting device. The wafer temperature adjusting device adjusts the temperature of a wafer to be processed in a vacuum processing chamber at least one of ‘before processing’, ‘during processing’, and ‘after processing’. The wafer temperature adjusting device is used, for example, to heat or cool the wafer before processing, in order to process the wafer in a high-temperature state or a low-temperature state in the vacuum processing chamber. The wafer temperature adjusting device is used to cool or heat the wafer after processing in order to bring the wafer processed in the high-temperature state or the low-temperature state to room temperature or a temperature close to room temperature. Here, the high-temperature state means a state with a temperature higher than room temperature by 20° C. or higher, 50° C. or higher, or 100° C. or higher, and the low-temperature state means a state with a temperature lower than room temperature by −20° C. or lower, −50° C. or lower, or −100° C. or lower. The temperature of the wafer to be processed in the vacuum processing chamber is set in a range of, for example, −200° C. to 500° C.

The wafer temperature adjusting device according to the present embodiment has a simpler structure than related arts and enables uniform and quick temperature adjustment. The wafer temperature adjusting device includes an upper surface, a wafer support mechanism that supports the wafer in a state where the distance between the upper surface and the wafer is maintained within a predetermined range, a stage that adjusts a temperature of the upper surface, and a gas supply unit that supplies a heat transfer gas to a space between the upper surface and the wafer. For example, by supplying the heat transfer gas of 5 torr or more to the space between the upper surface and the wafer in a state where the distance between the upper surface and the wafer is maintained within the predetermined range (for example, 10 μm to 30 μm), a heat transfer between the stage and the wafer can be accelerate, and the temperature of the wafer can be adjusted in a short time of about several seconds.

In the present embodiment, since the heat transfer gas is supplied not only between the upper surface of the stage and the wafer but also to above the wafer, there is no pressure difference of gas between a lower side (back surface side) and an upper side (front surface side) of the wafer. As a result, it is not necessary to bring the upper surface of the stage into close contact with the wafer to confine the heat transfer gas, and a wafer holding device such as an electrostatic chuck for bringing the upper surface of the stage into close contact with the wafer is not required. That is, the temperature of the wafer can be uniformly and quickly adjusted in a state where the wafer is simply disposed above the stage. Accordingly, according to the present embodiment, a complicated configuration for holding the wafer is not required, and it is also possible to suppress an increase in back surface particles generated by rubbing the wafer by bringing the wafer into close contact with the upper surface of the stage.

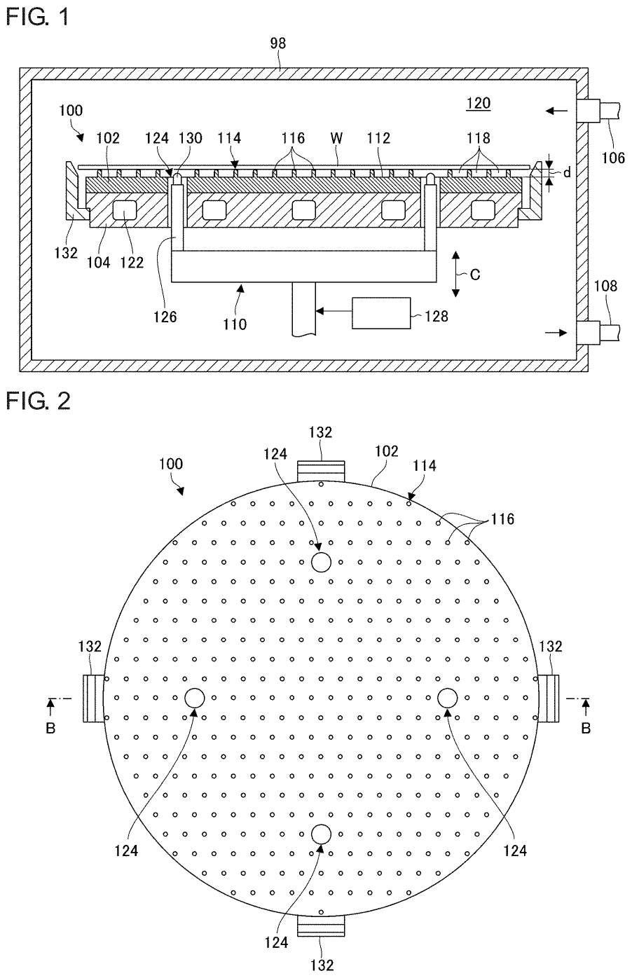

FIG. 1 is a sectional view showing a schematic configuration of a wafer temperature adjusting device 100 according to the embodiment. The wafer temperature adjusting device 100 is provided inside a temperature adjusting chamber 98. The wafer temperature adjusting device 100 includes a support plate 102, a stage 104, a gas supply unit 106, a gas exhaust unit 108, and a lift-up mechanism 110.

The support plate 102 is provided on the stage 104. The support plate 102 has an upper surface 112 and a wafer support mechanism 114. The wafer support mechanism 114 supports the wafer W above the upper surface 112 such that a distance d between the upper surface 112 and the wafer W is maintained within the predetermined range. The wafer support mechanism 114 supports the wafer W in a state where a first space 118 between the upper surface 112 and the wafer W and a second space 120 above the wafer W communicate with each other.

A heat transfer gas is supplied to the first space 118 between the upper surface 112 and the wafer W through the gas supply unit 106. The heat transfer gas present in the first space 118 promotes heat transfer between the upper surface 112 and the wafer W. For example, in a case where the temperature of the upper surface 112 is higher than the temperature of the wafer W, the wafer W receives heat energy from the upper surface 112 via the heat transfer gas present in the first space 118. Accordingly, the wafer W is heated. On the contrary, in a case where the temperature of the upper surface 112 is lower than the temperature of the wafer W, the upper surface 112 receives heat energy from the wafer W via the heat transfer gas present in the first space 118. Accordingly, the wafer W is cooled.

The wafer support mechanism 114 has a plurality of protrusions 116 that protrude from the upper surface 112. The height of each of the plurality of protrusions 116 corresponds to the distance d between the upper surface 112 and the wafer W. The respective heights of the plurality of protrusions 116 are preferably the same, and the distance d between the upper surface 112 and the wafer W is preferably configured to be constant on the entire surface of the wafer W. The distance d between the upper surface 112 and the wafer W is 0.1 μm or more and 1,000 μm or less, preferably 5 μm or more and 100 μm or less. The distance d between the upper surface 112 and the wafer W is, for example, about 10 μm to 30 μm. By suitably setting the distance d between the upper surface 112 and the wafer W, the temperature of the wafer W can be adjusted in a shorter time. Specifically, by reducing the distance d between the upper surface 112 and the wafer W to 1,000 μm or less, it is possible to induce heat transfer in which heat conduction is dominant instead of heat transfer in which convection is dominant, and heat transfer rate can be significantly increased.

The support plate 102 is made of a material having high thermal conductivity. The support plate 102 is made of a ceramic material such as aluminum nitride (AlN), alumina (Al₂O₃), silicon carbide (SiC), or silicon nitride (SiN), a metal material such as aluminum or stainless steel, a composite material containing ceramic and metal, or the like. The support plate 102 may be made of a composite material in which a porous ceramic body of SiC is impregnated with metallic silicon.

The material constituting the upper surface 112 of the support plate 102 may be the same as or different from the material constituting the plurality of protrusions 116. For example, each of the upper surface 112 and the plurality of protrusions 116 may be made of a ceramic material, a composite material containing ceramic, or the like which has high thermal conductivity. In addition, only the upper surface 112 may be made of a material having high thermal conductivity, and the plurality of protrusions 116 may be made of a material having lower thermal conductivity than the upper surface 112. For example, the plurality of protrusions 116 may be made of a synthetic resin material such as polyimide or polyetheretherketone (PEEK).

The stage 104 supports the support plate 102. The stage 104 physically contacts the support plate 102, thereby adjusting the temperature of the support plate 102 such that the upper surface 112 of the support plate 102 reaches a desired temperature. The stage 104 has a flow path 122 through which a temperature adjusting fluid for adjusting the temperature of the upper surface 112 flows. By adjusting the temperature of the temperature adjusting fluid to be supplied to the flow path 122, the temperature of the stage 104 can be adjusted, and the temperature of the upper surface 112 of the support plate 102 can be adjusted. The stage 104 may include a heater for temperature adjustment in addition to or instead of the flow path 122.

The stage 104 is made of a material having high thermal conductivity. The stage 104 is made of a ceramic material such as aluminum nitride (AlN), alumina (Al₂O₃), silicon carbide (SiC), or silicon nitride (SiN), a metal material such as aluminum or stainless steel, a composite material containing ceramic and metal, or the like. The stage 104 may be made of the same material as that of the support plate 102 or may be made of a material different from that of the support plate 102.

The support plate 102 may be detachably attached to the stage 104. That is, the wafer support mechanism 114 and the plurality of protrusions 116 may be detachably attached to the stage 104. The support plate 102 may be formed integrally with the stage 104. For example, the stage 104 may have the upper surface 112 and may be configured such that the plurality of protrusions 116 protrude from the upper surface 112 of the stage 104. In this case, at least one of the plurality of protrusions 116 may be detachably attached to the upper surface 112 of the stage 104. For example, some of the plurality of protrusions 116 may be detachably attached to the upper surface 112, and the remaining some of the plurality of protrusions 116 may be formed integrally with the upper surface 112. Additionally, all of the plurality of protrusions 116 may be detachably attached to the upper surface 112 of the stage 104.

The gas supply unit 106 supplies the heat transfer gas to the inside of the temperature adjusting chamber 98, thereby supplying the heat transfer gas to the first space 118 between the upper surface 112 and the wafer W and the second space 120 above the wafer W. The mounting position of the gas supply unit 106 is not particularly limited, but the gas supply unit 106 is provided, for example, on a wall that partitions the temperature adjusting chamber 98. The gas supply unit 106 supplies dry air, nitrogen gas, rare gas such as argon (Ar) or helium (He), or mixture thereof as the heat transfer gas.

The gas supply unit 106 supplies the heat transfer gas having a pressure of 1 torr or more, preferably 5 torr or more. The gas supply unit 106 supplies the heat transfer gas having a pressure such that a mean free path λ of the heat transfer gas is smaller than the distanced between the upper surface 112 and the wafer W in the first space 118 (that is, d>λ). The mean free path λ of the heat transfer gas is expressed as λ=k_{B}T/(√2πσ²P). Here, k_{B} is the Boltzmann constant, T is an absolute temperature, σ is a diameter of a molecule constituting the heat transfer gas, and P is the pressure of the heat transfer gas.

For example, the mean free path λ of the nitrogen gas (N₂) at room temperature (27° C.) is about 50 μm in a case where the pressure P=1 torr and about 1 μm in a case where the pressure is 50 torr. In a case where the distance d between the upper surface 112 and the wafer W is 1 μm, the pressure P of the nitrogen gas satisfying the condition of d>λ is 50 torr or more. In a case where the distance d between the upper surface 112 and the wafer W is 10 μm, the pressure P of the nitrogen gas satisfying the condition of d>λ is 5 torr or more. By supplying the heat transfer gas satisfying the condition of d>λ, the heat conduction caused by the collision between the gas molecules constituting the heat transfer gas becomes dominant in the first space 118. Therefore, the heat transfer in the first space 118 can be promoted. Accordingly, the time required for the temperature adjustment of the wafer W can be shortened as compared to a case where the condition of d>λ is not satisfied.

In a case where the condition of d>λ is satisfied for the pressure P of the heat transfer gas, the heat transfer between the upper surface 112 of the wafer temperature adjusting device 100 and the wafer W is dominated by heat conduction or convection depending on the distanced between the upper surface 112 and the wafer W. In a case where the distance d between the upper surface 112 and the wafer W is sufficiently large, for example, in a case where d>10,000 μm, the heat transfer between the upper surface 112 and the wafer W is dominated by convection. In a case where convection is dominant, the flow of the heat transfer gas should be sufficiently fast in order to increase the heat transfer rate. However, in order to speed up the flow of the heat transfer gas, a device for forcibly convecting the heat transfer gas is required. In this case, it is necessary to hold the wafer W with an electrostatic chuck or the like such that the wafer W does not move, and the configuration of the device becomes complicated. On the other hand, in a case where the distance d between the upper surface 112 and the wafer W is sufficiently small, for example, in a case where d≤1,000 μm, heat conduction becomes dominant in the heat transfer. In this case, since the heat transfer rate between the upper surface 112 and the wafer W is inversely proportional to the distance d, the heat transfer rate can be increased by reducing the distance d. In this case, it is not necessary to forcibly convect the heat transfer gas in order to increase the heat transfer rate.

For example, in a case where the distance d between the upper surface 112 and the wafer W is 10 μm, the pressure P of the nitrogen gas supplied as the heat transfer gas is 5 torr, the temperature of the upper surface 112 is room temperature (27° C.), and the temperature of the wafer W is 200° C., the time required for the temperature of the wafer W to reach room temperature from 200° C. is about 10 seconds. In addition, by increasing the pressure P of the heat transfer gas to further reduce the mean free path λ, the time required for the temperature adjustment of the wafer W can be further shortened. For example, in a case where the distance d between the upper surface 112 and the wafer W is 10 μm and the pressure P of the nitrogen gas is 50 torr which is 10 times of 5 torr, that is, in a case where the condition d>10λ is satisfied, the time required for the temperature of the wafer W to reach room temperature from 200° C. is about 1 second.

In addition, the pressure P of the heat transfer gas may be set so as to correspond to a viscous flow region in which the Knudsen number Kn=λ/d is 0.01 or less (that is, d≥100λ). Additionally, the distance d and the pressure P of the heat transfer gas may be set so as to correspond to an intermediate flow region in which the Knudsen number Kn is 0.01 to 0.3 (that is, 3.33λ<d<100λ). The distance d and the pressure P of the heat transfer gas may be set so as to correspond to a molecular flow region in which the Knudsen number Kn is 0.3 or more (that is, d≤3.33λ).

The gas supply unit 106 may supply the heat transfer gas having atmospheric pressure (that is, about 760 torr). The temperature adjusting chamber 98 may be a load lock chamber for transporting wafers between the vacuum processing chamber and the air atmosphere. In a case where the temperature adjusting chamber 98 is the load lock chamber, the gas supply unit 106 may supply the heat transfer gas having atmospheric pressure such that the pressure in the load lock chamber becomes atmospheric pressure. That is, the gas supply unit 106 may supply the heat transfer gas having atmospheric pressure as a preparation step for opening the load lock chamber to the air atmosphere. Since the heat transfer gas having atmospheric pressure satisfies the condition of d>10λ, the temperature of the wafer W can be adjusted in an extremely short time (for example, 1 second or less). The gas supply unit 106 may supply the heat transfer gas having a pressure exceeding atmospheric pressure.

The gas exhaust unit 108 exhausts the heat transfer gas inside the temperature adjusting chamber 98 to the outside and evacuates the temperature adjusting chamber 98. For example, a roughing vacuum pump such as an oil rotary vacuum pump or a dry vacuum pump is connected to the gas exhaust unit 108. The heat transfer gas exhausted through the gas exhaust unit 108 may be recovered in a gas cylinder (not shown) or the like. The heat transfer gas recovered in the gas cylinder or the like may be reused as the heat transfer gas supplied from the gas supply unit 106.

The lift-up mechanism 110 lifts the wafer W from below to support the wafer W apart from the plurality of protrusions 116. By lifting the wafer W, the lift-up mechanism 110 forms a gap between the wafer W and the plurality of protrusions 116 into which a wafer handler attached to a tip of the wafer transport robot arm enters. The lift-up mechanism 110 lifts the wafer W such that the distance between the wafer W and the plurality of protrusions 116 is, for example, 10 mm (that is, 10,000 μm) or more. The lift-up mechanism 110 includes a plurality of lift pins 126 and a drive mechanism 128 that drives the plurality of lift pins 126 in a vertical direction (direction of arrow C). The plurality of lift pins 126 are respectively provided in a plurality of through-holes 124 penetrating the support plate 102 and the stage 104. Tips 130 of the lift pins 126 are made of a material that does not easily contaminate the wafer W, and are made of, for example, quartz (SiO₂) or PEEK.

Wafer guides 132 are provided at an outer periphery of the support plate 102 and the stage 104. The wafer guides 132 are provided so as to face an outer periphery of the wafer W disposed on the plurality of protrusions 116. The wafer guides 132 restrict radial displacement of the wafer W. The wafer guides 132 prevent the position of the wafer W from being significantly shifted when the wafer W is disposed on the plurality of protrusions 116 or when the heat transfer gas is supplied.

FIG. 2 is a top view showing a schematic configuration of the wafer temperature adjusting device 100 of FIG. 1. FIG. 1 corresponds to a cross-section taken along a line B-B of FIG. 2. FIG. 2 shows the disposition of a plurality of protrusions 116 provided on the upper surface 112 of the support plate 102. As shown, the plurality of protrusions 116 are disposed in a two-dimensional array on the upper surface 112 of the support plate 102. Since the plurality of protrusions 116 are provided apart from each other, the first space 118 between the wafer W disposed on the plurality of protrusions 116 and the upper surface 112 is a space that is open without being sealed. As a result, when the heat transfer gas is supplied from the gas supply unit 106, the heat transfer gas is supplied to the first space 118 through the outer periphery of the wafer W and the through-hole 124.

Sum of formation areas of the plurality of protrusions 116 is 50% or less, preferably 20% or less or 10% or less of the entire area of the upper surface 112. By reducing the sum of formation areas of the plurality of protrusions 116, the area where the wafer W and the remaining upper surface 112 face each other can be increased, and the heat transfer between the wafer W and the upper surface 112 can be further promoted.

The number of the plurality of protrusions 116 is 0.01 or more and 10,000 or less, preferably 0.1 or more and 10 or less, per 1 cm² area of the upper surface 112. By setting the number of the plurality of protrusions 116 to the lower limit value or more, the distance d between the wafer W and the upper surface 112 can be made uniform over the entire wafer, and the temperature of the entire wafer W can be efficiently adjusted to suppress temperature unevenness. By setting the number of the plurality of protrusions 116 to the upper limit value or less, the area where the wafer W and the upper surface 112 face each other can be increased, and the heat transfer between the wafer W and the upper surface 112 can be further promoted.

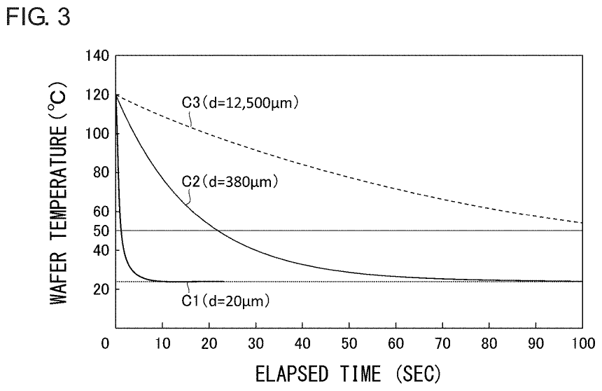

FIG. 3 is a graph schematically showing adjustment times of wafer temperature. FIG. 3 shows the times required for the temperature of the wafer W to be cooled from 120° C. to 50° C. or lower in a case where the distance d between the upper surface 112 and the wafer W is set to 20 μm (curve C1), 380 μm (curve C2) and 12,500 μm (curve C3). The wafer W is a silicon substrate having a diameter of 300 mm. The temperature of the upper surface 112 is adjusted to room temperature (24° C.). The heat transfer gas supplied between the wafer W and the upper surface 112 is nitrogen gas having atmospheric pressure. In a case where the distance d=20 μm, the wafer W can be cooled to 50° C. or lower in about 2 seconds, and the wafer W can be cooled to the same temperature as the temperature of the upper surface 112 in about 10 seconds. In a case where the distance d=380 μm, the wafer W can be cooled to 50° C. or lower in about 20 seconds, and the wafer W can be cooled to the same temperature as the temperature of the upper surface 112 in about 100 seconds. In a case where the distance d=12,500 μm, the time exceeding 100 seconds is required to cool the wafer W to 50° C. or lower. In a case where the distance d=12,500 μm, the heat transfer caused by convection becomes dominant, and the heat transfer rate is significantly reduced.

Next, an operation example of the wafer temperature adjusting device 100 will be described. First, the wafer W is loaded into the temperature adjusting chamber 98, and the wafer W is disposed on the wafer support mechanism 114. When the wafer W is disposed, the wafer W may be disposed on the lift pins 126 first by locating the tips 130 of the lift pins 126 above the wafer support mechanism 114. After that, the wafer W may be disposed on the wafer support mechanism 114 by moving the lift pins 126 downward. Accordingly, the wafer W is supported above the upper surface 112 in a state where the distance d between the upper surface 112 and the wafer W is maintained within the predetermined range, and the first space 118 between the upper surface 112 and the wafer W communicates with the second space 120 above the wafer W. Next, the heat transfer gas is supplied to the inside of the temperature adjusting chamber 98 through the gas supply unit 106. The heat transfer gas is supplied to the second space 120 and also to the first space 118. The supply of the heat transfer gas may be started in a state where the wafer W is disposed on the lift pins 126, that is, in a state where the wafer W is separated from the plurality of protrusions 116. The supply of the heat transfer gas may be executed only in a state where the wafer W is disposed on the lift pins 126, that is, in a state where the wafer W is separated from the plurality of protrusions 116, or may be completed before the wafer W is disposed on the wafer support mechanism 114. The supply of the heat transfer gas may be started in a state where the wafer W is separated from the plurality of protrusions 116 and may be continued in a state where the wafer W is disposed on the wafer support mechanism 114.

The heat transfer gas supplied to the first space 118 promotes the heat transfer between the upper surface 112 and the wafer W. As a result, the temperature of the wafer W is adjusted to the same temperature as the temperature of the upper surface 112 after an elapse of a predetermined time. The temperature adjustment of the wafer W may be completed before the temperature of the wafer W reaches the same temperature as the temperature of the upper surface 112. In this case, the temperature of the wafer W after the adjustment may be different from the temperature of the upper surface 112. After the temperature adjustment of the wafer W is completed, the wafer W is unloaded to the outside of the temperature adjusting chamber 98. In a case where the wafer W is unloaded, the wafer W may be lifted upward by the lift pins 126 to form a gap for inserting the wafer handler between the wafer W and the wafer support mechanism 114.

In a case where the temperature adjusting chamber 98 is the load lock chamber, the wafer temperature adjusting device 100 may adjust the temperature of the wafer W when the wafer W is unloaded from the vacuum processing chamber to the air atmosphere. For example, by supplying the heat transfer gas having atmospheric pressure to the temperature adjusting chamber 98, it is possible to simultaneously execute the opening of the temperature adjusting chamber 98 to the air atmosphere and the temperature adjustment of the wafer W. The wafer temperature adjusting device 100 may adjust the temperature of the wafer W to room temperature or a temperature close to room temperature. For example, when the wafer W having a temperature higher than room temperature is unloaded to the air atmosphere, there is a possibility that oxygen, nitrogen, moisture, or the like contained in the air atmosphere reacts with the wafer W to change the characteristics of the wafer W. Additionally, when the wafer W having a temperature lower than room temperature is unloaded to the air atmosphere, there is a possibility that moisture contained in the air atmosphere condenses on the wafer W or adheres to the wafer W as frost. By returning the temperature of the wafer W to room temperature or a temperature close to room temperature in the wafer temperature adjusting device 100 and then unloading the wafer W to the air atmosphere, the wafer W can be suitably handled in the air atmosphere.

In a case where the temperature adjusting chamber 98 is the load lock chamber, the wafer temperature adjusting device 100 may adjust the temperature of the wafer W when the wafer W is loaded into the vacuum processing chamber from the air atmosphere. For example, by evacuating the temperature adjusting chamber 98 and supplying the heat transfer gas of about 1 to 500 torr, an internal pressure of the temperature adjusting chamber 98 may be lowered while the gas inside the temperature adjusting chamber 98 is substituted with the heat transfer gas. Accordingly, the evacuation of the temperature adjusting chamber 98 and the temperature adjustment of the wafer W can be simultaneously executed. During the temperature adjustment of the wafer W, the evacuation of the temperature adjusting chamber 98 may be temporarily stopped, or the supply of the heat transfer gas and the evacuation may be simultaneously performed. After the temperature adjustment of the wafer W is completed, the temperature adjusting chamber 98 may be evacuated to reduce the pressure in the temperature adjusting chamber 98 to less than 1 torr. The wafer temperature adjusting device 100 may adjust the temperature of the wafer W such that the temperature is brought into a high-temperature state or a low-temperature state. By adjusting the temperature of the wafer W before the processing in the vacuum processing chamber, the time required for adjusting the temperature of the wafer W in the vacuum processing chamber can be shortened, and the productivity can be increased.

The above-described wafer temperature adjusting device 100 can be used as a wafer processing apparatus for processing the wafer in the vacuum processing chamber. For example, the wafer processing apparatus may include the vacuum processing chamber in which a process on the wafer is performed, the wafer temperature adjusting device 100, the temperature adjusting chamber 98, a gate valve capable of sealing between the vacuum processing chamber and the temperature adjusting chamber 98, and an evacuation device that reduces a pressure in the temperature adjusting chamber 98. The wafer processing apparatus may be an ion implanter to be described in detail below.

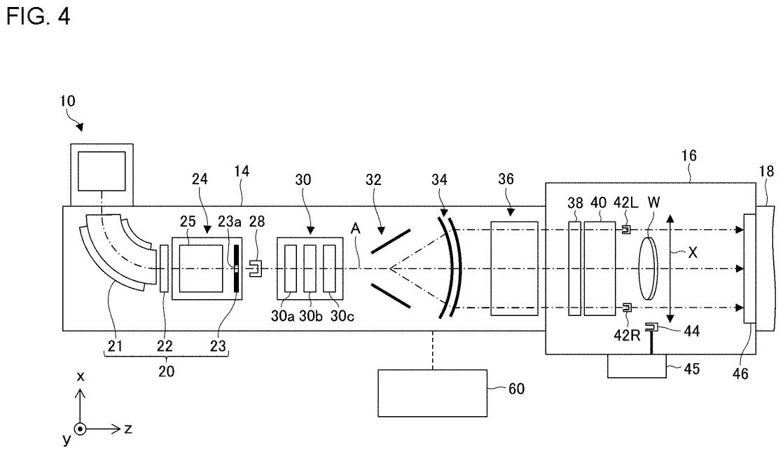

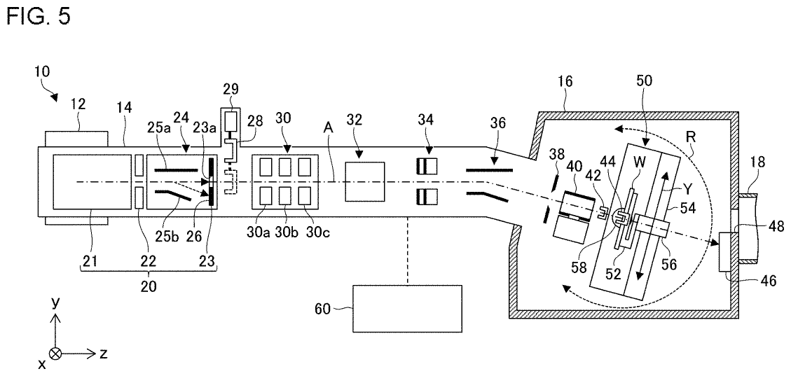

FIG. 4 is a top view schematically showing an ion implanter 10 according to the embodiment, and FIG. 5 is a side view showing a schematic configuration of the ion implanter 10. The ion implanter 10 is configured to perform an ion implantation process on the front surface of an object W to be processed. The object W to be processed is, for example, a substrate or, for example, a semiconductor wafer. For the convenience of explanation, the object W to be processed is sometimes referred to as the wafer W in the present specification, but this is not intended to limit a target of implantation processing to a specific object.

The ion implanter 10 is configured to perform reciprocating scanning in one direction with a beam and reciprocate the wafer W in another direction perpendicular to the scanning direction to irradiate the entire processing surface of the wafer W with an ion beam. In the present specification, for convenience of explanation, a traveling direction of the ion beam which travels along a designed beamline A is defined as a z direction, and a plane perpendicular to the z direction is defined as an xy plane. In a case where the object W to be processed is scanned with the ion beam, the scanning direction of the beam is defined as an x direction, and a direction perpendicular to the z direction and the x direction is defined as a y direction. Accordingly, the reciprocating scanning with the beam is performed in the x direction, and the reciprocating motion of the wafer W is performed in the y direction.

The ion implanter 10 includes an ion generation device 12, a beamline unit 14, an implantation processing chamber 16, and a wafer transport device 18. The ion generation device 12 is configured to introduce the ion beam to the beamline unit 14. The beamline unit 14 is configured to transport the ion beam from the ion generation device 12 to the implantation processing chamber 16. The wafer W serving as an implantation target is accommodated in the implantation processing chamber 16, and an implantation process is performed in which the wafer W is irradiated with the ion beam imparted from the beamline unit 14. The wafer transport device 18 is configured to load an unprocessed wafer before the implantation process into the implantation processing chamber 16 and to unload a processed wafer after the implantation process from the implantation processing chamber 16. The ion implanter 10 includes an evacuation system (not shown) for providing desired vacuum environments to the ion generation device 12, the beamline unit 14, the implantation processing chamber 16, and the wafer transport device 18.

The beamline unit 14 includes a mass analyzing unit 20, a beam park device 24, a beam shaping unit 30, a beam scanning unit 32, a beam parallelizing unit 34, and an angular energy filter (AEF) 36 in this order from an upstream side of the beamline A. In addition, the upstream side of the beamline A means a side closer to the ion generation device 12, and a downstream side of the beamline A means a side closer to the implantation processing chamber 16 (or a beam stopper 46).

The mass analyzing unit 20 is provided downstream of the ion generation device 12 and is configured to select a required ion species from the ion beam extracted from the ion generation device 12 by mass analysis. The mass analyzing unit 20 includes a mass analyzing magnet 21, a mass analyzing lens 22, and a mass analyzing slit 23.

The mass analyzing magnet 21 applies a magnetic field to the ion beam extracted from the ion generation device 12 and deflects the ion beam to travel in different paths depending on a value of a mass-to-charge ratio M=m/q (m is mass and q is a charge) of ions. The mass analyzing magnet 21, for example, applies a magnetic field in the y direction (−y direction in FIGS. 4 and 5) to the ion beam to deflect the ion beam in the x direction. Magnetic field intensity of the mass analyzing magnet 21 is adjusted such that the ion species having a desired mass-to-charge ratio M passes through the mass analyzing slit 23.

The mass analyzing lens 22 is provided downstream of the mass analyzing magnet 21 and is configured to adjust the focusing/defocusing power with respect to the ion beam. The mass analyzing lens 22 adjusts a focusing position of the ion beam passing through the mass analyzing slit 23 in a beam traveling direction (z direction) and adjusts a mass resolution M/dM of the mass analyzing unit 20. In addition, the mass analyzing lens 22 is not an essential configuration, and the mass analyzing lens 22 may not be provided in the mass analyzing unit 20.

The mass analyzing slit 23 is provided downstream of the mass analyzing lens 22 and is provided at a position apart from the mass analyzing lens 22. The mass analyzing slit 23 is configured such that a beam deflection direction (x direction) caused by the mass analyzing magnet 21 coincides with a slit width direction, and has an opening 23a having a shape that is relatively short in the x direction and is relatively long in the y direction.

The mass analyzing slit 23 may be configured such that the slit width is variable for the adjustment of the mass resolution. The mass analyzing slit 23 may include two shield members that are movable in the slit width direction, and the slit width may be adjusted by changing a distance between the two shield members. The mass analyzing slit 23 may be configured such that the slit width is variable by being switched to any one of a plurality of slits having different slit widths.

The beam park device 24 is configured to temporarily retract the ion beam from the beamline A and shield the ion beam directed toward the implantation processing chamber 16 (or wafer W) located downstream. The beam park device 24 can be disposed at an optional position in the middle of the beamline A and can be disposed, for example, between the mass analyzing lens 22 and the mass analyzing slit 23. A certain distance is required between the mass analyzing lens 22 and the mass analyzing slit 23. Therefore, by disposing the beam park device 24 between the mass analyzing lens 22 and the mass analyzing slit 23, a length of the beamline A can be shortened as compared to a case where the beam park device 24 is disposed at another position, and the entire ion implanter 10 can be downsized.

The beam park device 24 includes a pair of park electrodes 25 (25a, 25b) and a beam dump 26. The pair of park electrodes 25a and 25b face each other with the beamline A interposed therebetween and faces each other in a direction (y direction) perpendicular to the beam deflection direction (x direction) by the mass analyzing magnet 21. The beam dump 26 is provided on the downstream side of the beamline A with respect to the park electrodes 25a and 25b and is provided apart from the beamline A in a facing direction of the park electrodes 25a and 25b.

The first park electrode 25a is disposed above the beamline A in the direction of gravity, and the second park electrode 25b is disposed below the beamline A in the direction of gravity. The beam dump 26 is provided at a position separated downward from the beamline A in the direction of gravity and is disposed below the opening 23a of the mass analyzing slit 23 in the direction of gravity. The beam dump 26 is composed of, for example, a portion of the mass analyzing slit 23 in which the opening 23a is not formed. The beam dump 26 may be configured as a separate body from the mass analyzing slit 23.

The beam park device 24 deflects the ion beam by utilizing an electric field applied between the pair of park electrodes 25a and 25b and retracts the ion beam from the beamline A. For example, by applying a negative voltage to the second park electrode 25b with reference to an electric potential of the first park electrode 25a, the ion beam is deflected downward from the beamline A in the direction of gravity and made incident into the beam dump 26. In FIG. 5, the trajectory of the ion beam directed toward the beam dump 26 is shown by a broken line. Additionally, the beam park device 24 allows the ion beam to pass toward the downstream side along the beamline A by causing the pair of park electrodes 25a and 25b to have the same electric potential. The beam park device 24 is configured to be operable by switching between a first mode in which the ion beam is allowed to pass toward the downstream side and a second mode in which the ion beam is made incident into the beam dump 26.

An injector Faraday cup 28 is provided downstream of the mass analyzing slit 23. The injector Faraday cup 28 is configured so as to be capable of being moved into and out of the beamline A by an operation of an injector drive unit 29. The injector drive unit 29 moves the injector Faraday cup 28 in the direction (for example, the y direction) perpendicular to an extending direction of the beamline A. In a case where the injector Faraday cup 28 is disposed on the beamline A as shown by a broken line in FIG. 5, the injector Faraday cup 28 blocks the ion beam directed toward the downstream side. On the other hand, in a case where the injector Faraday cup 28 is removed from the beamline A as shown by a solid line in FIG. 5, the blocking of the ion beam directed toward the downstream side is released.

The injector Faraday cup 28 is configured to measure the beam current of the ion beam mass-analyzed by the mass analyzing unit 20. The injector Faraday cup 28 can measure a mass analysis spectrum of the ion beam by measuring the beam current while changing the magnetic field intensity of the mass analyzing magnet 21. The mass resolution of the mass analyzing unit 20 can be calculated using the measured mass analysis spectrum.

The beam shaping unit 30 includes a focusing/defocusing device such as a focusing/defocusing quadrupole lens (Q lens) and is configured to shape the ion beam that has passed through the mass analyzing unit 20 into a desired cross-sectional shape. The beam shaping unit 30 is composed of, for example, an electric field type three-stage quadrupole lens (also referred to as a triplet Q lens) and has three quadrupole lenses 30a, 30b, and 30c. The beam shaping unit 30 can independently adjust the convergence or divergence of the ion beam in the x direction and the y direction by using the three quadrupole lenses 30a, 30b, and 30c. The beam shaping unit 30 may include a magnetic field type lens device or may include a lens device that shapes a beam by utilizing both an electric field and a magnetic field.

The beam scanning unit 32 is a beam deflection device that is configured to provide reciprocating scanning of the beam and to perform scanning with the shaped ion beam in the x direction. The beam scanning unit 32 has a pair of scanning electrodes that faces each other in a beam scanning direction (x direction). The pair of scanning electrodes is connected to variable voltage power supplies (not shown), and a voltage applied between the pair of scanning electrodes is periodically changed to change an electric field generated between the electrodes such that the ion beam is deflected at various angles. As a result, the entire scanning range in the x direction is scanned with the ion beam. In FIG. 4, the scanning direction and scanning range of the beam are exemplified by an arrow X, and a plurality of trajectories of the ion beam in the scanning range are shown by one dot chain lines.

The beam parallelizing unit 34 is configured to make the traveling directions of the scanning ion beam parallel to the trajectory of the designed beamline A. The beam parallelizing unit 34 has a plurality of arc-shaped parallelizing lens electrodes in each of which an ion beam passing slit is provided at a central portion in the y direction. The parallelizing lens electrodes are connected to high-voltage power supplies (not shown), and an electric field generated by applying voltages is made to act on the ion beam to align the traveling directions of the ion beam in parallel. In addition, the beam parallelizing unit 34 may be substituted with another beam parallelizing device, and the another beam parallelizing device may be configured as a magnetic device utilizing a magnetic field.

An acceleration/deceleration (AD) column (not shown) for accelerating or decelerating the ion beam may be provided downstream of the beam parallelizing unit 34.

The angular energy filter (AEF) 36 is configured to analyze energy of the ion beam, to deflect the ions having required energy downward at a prescribed angle, and to guide the ions to the implantation processing chamber 16. The angular energy filter 36 has a pair of AEF electrodes for deflection by an electric field. The pair of AEF electrode is connected to high-voltage power supplies (not shown). In FIG. 5, the ion beam is deflected downward by applying a positive voltage to the upper AEF electrode and a negative voltage to the lower AEF electrode. In addition, the angular energy filter 36 may be composed of a magnetic device for deflection by a magnetic field or may be composed of a combination of the pair of AEF electrodes for deflection by the electric field and the magnetic device for deflection by the magnetic field.

In this way, the beamline unit 14 supplies the ion beam with which the wafer W is to be irradiated to the implantation processing chamber 16.

The implantation processing chamber 16 includes an energy slit 38, a plasma shower device 40, side cups 42, a center cup 44, and the beam stopper 46 in this order from the upstream side of the beamline A. As shown in FIG. 5, the implantation processing chamber 16 includes a platen driving device 50 that holds one or a plurality of wafers W.

The energy slit 38 is provided downstream of the angular energy filter 36 and analyzes the energy of the ion beam incident into the wafer W together with the angular energy filter 36. The energy slit 38 is an energy defining slit (EDS) composed of a slit that is horizontally long in the beam scanning direction (x direction). The energy slit 38 allows the ion beam having a desired energy value or a desired energy range to pass toward the wafer W and shields the other ion beams.

The plasma shower device 40 is located downstream of the energy slit 38. The plasma shower device 40 supplies low-energy electrons to the ion beam and the front surface (wafer processing surface) of the wafer W depending on the amount of beam current of the ion beam and suppresses charge-up caused by the accumulation of positive charges on the wafer processing surface generated by the ion implantation. The plasma shower device 40 includes, for example, a shower tube through which the ion beam passes and a plasma generating device that supplies electrons into the shower tube.

The side cups 42 (42R, 42L) are configured to measure the beam current of the ion beam during the ion implantation process into the wafer W. As shown in FIG. 5, the side cups 42R and 42L are disposed so as to be shifted to the right and left (x direction) with respect to the wafer W disposed on the beamline A and are disposed at positions where the ion beam directed toward the wafer W are not blocked during the ion implantation. Since the scanning in the x direction is performed with the ion beam beyond a range where the wafer W is located, a part of the scanning beam is incident into the side cups 42R and 42L even during the ion implantation. Accordingly, the amount of beam current during the ion implantation process is measured by the side cups 42R and 42L.

The center cup 44 is configured to measure the beam current on the wafer processing surface. The center cup 44 is configured to be movable in the x direction by an operation of the drive unit 45, is retracted from an implantation position where the wafer W is located during the ion implantation, and is inserted into the implantation position when the wafer W is not located at the implantation position. The center cup 44 can measure the beam current over the entire beam scanning range in the x direction by measuring the beam current while moving in the x direction. The center cup 44 may be formed in an array in which a plurality of Faraday cups are aligned in the x direction such that the beam currents at a plurality of positions in the beam scanning direction (x direction) can be simultaneously measured.

At least one of the side cups 42 and the center cup 44 may include a single Faraday cup for measuring the amount of beam current or may include an angle measuring instrument for measuring angle information of the beam. The angle measuring instrument includes, for example, a slit and a plurality of current detecting units provided apart from the slit in the beam traveling direction (z direction). The angle measuring instrument can measure an angle component of the beam in the slit width direction by, for example, measuring the beam having passed through the slit with the plurality of current detecting units lined up in the slit width direction. At least one of the side cups 42 and the center cup 44 may include a first angle measuring instrument capable of measuring the angle information in the x direction or a second angle measuring instrument capable of measuring the angle information in the y direction.

The platen driving device 50 includes a wafer holding device 52, a reciprocating mechanism 54, a twist angle adjusting mechanism 56, and a tilt angle adjusting mechanism 58.

The wafer holding device 52 includes an electrostatic chuck for holding the wafer W, or the like. The wafer holding device 52 may include a temperature adjusting device for heating or cooling the wafer W into which ions are implanted. The wafer holding device 52 may include a heating device that heats the wafer W to a temperature higher than room temperature by 20° C. or higher, 50° C. or higher, or 100° C. or higher. The wafer holding device 52 may include a cooling device that cools the wafer W to a temperature lower than room temperature by −20° C. or lower, −50° C. or lower, or −100° C. or lower. The temperature of the wafer W affects a concentration distribution (implantation profile) of ions implanted into the wafer W and a state of crystal defects (implantation damage) formed in the wafer W by the ion implantation. The process of irradiating the wafer W having a temperature higher than room temperature with the ion beam is also referred to as high-temperature implantation. Additionally, the process of irradiating the wafer W having a temperature lower than room temperature with the ion beam is also referred to as low-temperature implantation.

The reciprocating mechanism 54 reciprocates the wafer held by the wafer holding device 52 in the y direction by reciprocating the wafer holding device 52 in a reciprocation direction (y direction) perpendicular to the beam scanning direction (x direction). In FIG. 2, the reciprocating motion of the wafer W is exemplified by an arrow Y.

The twist angle adjusting mechanism 56 is a mechanism that adjusts a rotation angle of the wafer W, and adjusts a twist angle between an alignment mark provided on an outer peripheral portion of the wafer and a reference position by rotating the wafer W with a normal line of the wafer processing surface as an axis. Here, the alignment mark of the wafer refers to a notch or an orientation flat provided on the outer peripheral portion of the wafer and refers to a mark that serves as a reference for an angular position in a crystal axis direction of the wafer or in a circumferential direction of the wafer. The twist angle adjusting mechanism 56 is provided between the wafer holding device 52 and the reciprocating mechanism 54 and is reciprocated together with the wafer holding device 52.

The tilt angle adjusting mechanism 58 is a mechanism that adjusts the tilting of the wafer W and adjusts the tilt angle between the traveling direction of the ion beam directed toward the wafer processing surface and the normal line of the wafer processing surface. In the present embodiment, out of a plurality of tilt angles of the wafer W, an angle having an axis in the x direction as a center axis of rotation is adjusted as the tilt angle. The tilt angle adjusting mechanism 58 is provided between the reciprocating mechanism 54 and an inner wall of the implantation processing chamber 16 and is configured to adjust the tilt angle of the wafer W by rotating the entire platen driving device 50 including the reciprocating mechanism 54 in an R direction.

The platen driving device 50 holds the wafer W such that the wafer W is movable between the implantation position where the wafer W is irradiated with the ion beam and a transport position where the wafer W is loaded or unloaded between the platen driving device 50 and the wafer transport device 18. FIG. 5 shows a state where the wafer W is located at the implantation position, and the platen driving device 50 holds the wafer W such that the beamline A and the wafer W intersect each other. The transport position of the wafer W corresponds to a position of the wafer holding device 52 when the wafer W is loaded or unloaded through a transport port 48 by a transport mechanism or a transport robot provided in the wafer transport device 18.

The beam stopper 46 is provided on the most downstream side of the beamline A and is mounted on, for example, the inner wall of the implantation processing chamber 16. In a case where the wafer W is not present on the beamline A, the ion beam is incident into the beam stopper 46. The beam stopper 46 is located near the transport port 48 that connects the implantation processing chamber 16 and the wafer transport device 18 to each other, and is provided at a position vertically below the transport port 48.

The ion implanter 10 further includes a control device 60. The control device 60 controls an overall operation of the ion implanter 10. The control device 60 is realized by an element or a machine device including a CPU or a memory of a computer in terms of hardware and is realized by a computer program or the like in terms of software. Various functions provided by the control device 60 can be realized by cooperation between the hardware and the software.

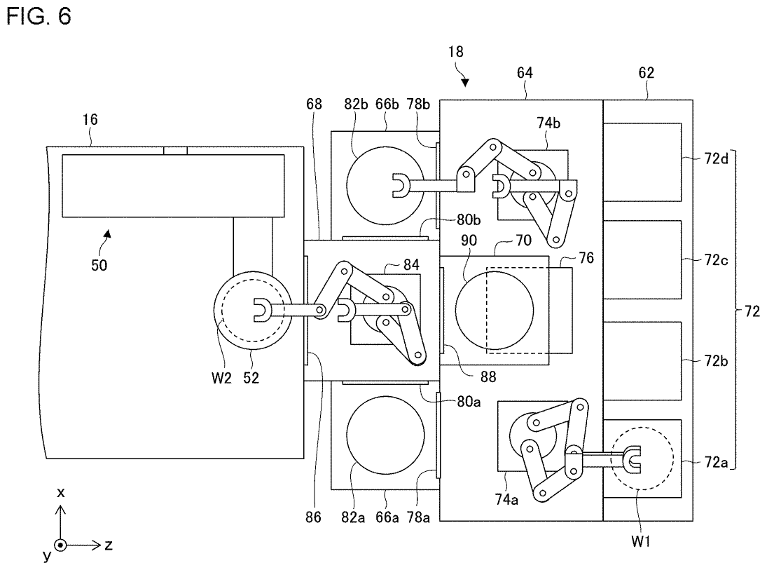

FIG. 6 is a top view showing a schematic configuration of the wafer transport device 18 according to the embodiment. The wafer transport device 18 includes a load port 62, an atmospheric transport unit 64, a first load lock chamber 66a, a second load lock chamber 66b, an intermediate transport chamber 68, and a buffer chamber 70.

The load port 62 can receive a plurality of wafer containers 72a, 72b, 72c, 72d (collectively referred to as wafer containers 72). The wafer transport device 18 is configured to load a wafer W1 stored in the wafer container 72 into the implantation processing chamber 16 and unload a wafer W2 subjected to the implantation process in the implantation processing chamber 16 into the wafer container 72.

The atmospheric transport unit 64 includes a first atmospheric transport mechanism 74a, a second atmospheric transport mechanism 74b, and an alignment device 76. The first atmospheric transport mechanism 74a is provided between the load port 62 and the first load lock chamber 66a. The first atmospheric transport mechanism 74a has, for example, two robot arms for transporting wafers. The first atmospheric transport mechanism 74a unloads the wafer before the implantation process from the first wafer container 72a or the second wafer container 72b and stores the implantation-processed wafer in the first wafer container 72a or the second wafer container 72b. The first atmospheric transport mechanism 74a loads the wafer before alignment into the alignment device 76 and unloads the aligned wafer from the alignment device 76. The first atmospheric transport mechanism 74a loads the aligned wafer into the first load lock chamber 66a and unloads the implantation-processed wafer from the first load lock chamber 66a.

The second atmospheric transport mechanism 74b is provided between the load port 62 and the second load lock chamber 66b. The second atmospheric transport mechanism 74b has, for example, two robot arms for transporting wafers. The second atmospheric transport mechanism 74b unloads the wafer before the implantation process from the third wafer container 72c or the fourth wafer container 72d and stores the implantation-processed wafer in the third wafer container 72c or the fourth wafer container 72d. The second atmospheric transport mechanism 74b loads the wafer before alignment into the alignment device 76 and unloads the aligned wafer from the alignment device 76. The second atmospheric transport mechanism 74b loads the aligned wafer into the second load lock chamber 66b and unloads the implantation-processed wafer from the second load lock chamber 66b.

The alignment device 76 is a device for adjusting a center position and a rotation position of the wafer. The alignment device 76 detects the alignment mark such as the notch provided on the wafer to adjust the center position and the rotation position of the wafer so as to be located at a desired position. Since the center position and the rotation position of the wafer taken out from the wafer container 72 are not necessarily aligned, the wafer is positioned (aligned) by using the alignment device 76 before being loaded into the load lock chambers 66a or 66b. The alignment device 76 is provided at a position between the first atmospheric transport mechanism 74a and the second atmospheric transport mechanism 74b. The alignment device 76 is provided, for example, at a position vertically below the buffer chamber 70.

Each of the first load lock chamber 66a and the second load lock chamber 66b is provided between the atmospheric transport unit 64 and the intermediate transport chamber 68. Each of the first load lock chamber 66a and the second load lock chamber 66b is, for example, adjacent to the atmospheric transport unit 64 in the z direction and adjacent to the intermediate transport chamber 68 in the x direction. The intermediate transport chamber 68 is provided adjacent to the implantation processing chamber 16 and is, for example, adjacent to the implantation processing chamber 16 in the z direction. The buffer chamber 70 is provided adjacent to the intermediate transport chamber 68 and is, for example, adjacent to the intermediate transport chamber 68 in the z direction.

The intermediate transport chamber 68 is maintained in a medium vacuum state of about 10⁻¹ Pa in a steady state. An evacuation (not shown) composed of a turbo molecular pump or the like is connected to the intermediate transport chamber 68. Meanwhile, the atmospheric transport unit 64 is provided under atmospheric pressure and transports the wafer in the air atmosphere. The first load lock chamber 66a and the second load lock chamber 66b are chambers that are partitioned to realize wafer transport between the intermediate transport chamber 68 maintained in the medium vacuum state and the atmospheric transport unit 64 in the air atmosphere. Each of the first load lock chamber 66a and the second load lock chamber 66b is configured to be able to be evacuated or opened to the air atmosphere during the wafer transport. A roughing vacuum pump such as an oil rotary vacuum pump or a dry vacuum pump is connected to each of the first load lock chamber 66a and the second load lock chamber 66b.

The first load lock chamber 66a includes a first atmospheric-side gate valve 78a provided between the first load lock chamber 66a and the atmospheric transport unit 64, a first intermediate gate valve 80a provided between the first load lock chamber 66a and the intermediate transport chamber 68, and a first temperature adjusting device 82a. Similarly, the second load lock chamber 66b includes a second atmospheric-side gate valve 78b provided between the second load lock chamber 66b and the atmospheric transport unit 64, a second intermediate gate valve 80b provided between the second load lock chamber 66b and the intermediate transport chamber 68, and a second temperature adjusting device 82b.

In a case where the first load lock chamber 66a is evacuated or opened to the air atmosphere, the first atmospheric-side gate valve 78a and the first intermediate gate valve 80a are closed. In a case where the wafer is transported between the atmospheric transport unit 64 and the first load lock chamber 66a, the first atmospheric-side gate valve 78a is opened in a state where the first intermediate gate valve 80a is closed. In a case where the wafer is transported between the intermediate transport chamber 68 and the first load lock chamber 66a, the first intermediate gate valve 80a is opened in a state where the first atmospheric-side gate valve 78a is closed.

Similarly, in a case where the second load lock chamber 66b is evacuated or opened to the air atmosphere, the second atmospheric-side gate valve 78b and the second intermediate gate valve 80b are closed. In a case where the wafer is transported between the atmospheric transport unit 64 and the second load lock chamber 66b, the second atmospheric-side gate valve 78b is opened in a state where the second intermediate gate valve 80b is closed. In a case where the wafer is transported between the intermediate transport chamber 68 and the second load lock chamber 66b, the second intermediate gate valve 80b is opened in a state where the second atmospheric-side gate valve 78b is closed.

The first temperature adjusting device 82a is configured to heat or cool the wafer loaded into the first load lock chamber 66a to adjust the wafer temperature. The first temperature adjusting device 82a may heat or cool the wafer before the implantation process to adjust the wafer temperature to a temperature suitable for the implantation process. The first temperature adjusting device 82a may cool or heat the implantation-processed wafer to adjust the wafer temperature to room temperature or a temperature close to room temperature.

The second temperature adjusting device 82b is configured to heat or cool the wafer loaded into the second load lock chamber 66b to adjust the wafer temperature. The second temperature adjusting device 82b may heat or cool the wafer before the implantation process to adjust the wafer temperature to a temperature suitable for the implantation process. The second temperature adjusting device 82b may cool or heat the implantation-processed wafer to adjust the wafer temperature to room temperature or a temperature close to room temperature.

The intermediate transport chamber 68 has an intermediate transport mechanism 84. The intermediate transport mechanism 84 has, for example, two robot arms for transporting wafers. The intermediate transport mechanism 84 transports the wafer between the intermediate transport chamber 68 and each of the chambers adjacent to the intermediate transport chamber 68. The intermediate transport mechanism 84 unloads the wafer before the implantation process from the first load lock chamber 66a and loads the implantation-processed wafer into the first load lock chamber 66a. The intermediate transport mechanism 84 unloads the wafer before the implantation process from the second load lock chamber 66b and loads the implantation-processed wafer into the second load lock chamber 66b. The intermediate transport mechanism 84 loads the wafer before the implantation process into the implantation processing chamber 16 and unloads the implantation-processed wafer from the implantation processing chamber 16. The intermediate transport mechanism 84 loads the wafer before the implantation process or the implantation-processed wafer into the buffer chamber 70 and unloads the wafer before the implantation process or the implantation-processed wafer from the buffer chamber 70.

A process chamber gate valve 86 is provided between the implantation processing chamber 16 and the intermediate transport chamber 68. The process chamber gate valve 86 is opened in a case where the wafer is transported between the implantation processing chamber 16 and the intermediate transport chamber 68. The process chamber gate valve 86 is closed in a case where the implantation process is performed on the wafer in the implantation processing chamber 16.

The buffer chamber 70 is a place for temporarily storing the wafer loaded into the intermediate transport chamber 68. The buffer chamber 70 has a buffer chamber gate valve 88 and a third temperature adjusting device 90. The buffer chamber gate valve 88 is provided between the intermediate transport chamber 68 and the buffer chamber 70. The buffer chamber gate valve 88 is opened in a case where the wafer is transported between the intermediate transport chamber 68 and the buffer chamber 70. The buffer chamber gate valve 88 is closed in a case where the wafer temperature is adjusted in the buffer chamber 70.

The third temperature adjusting device 90 is configured to heat or cool the wafer loaded into the buffer chamber 70 to adjust the temperature of the wafer. The third temperature adjusting device 90 may heat or cool the wafer before the implantation process to adjust the wafer temperature to be suitable for the implantation process. The third temperature adjusting device 90 may cool or heat the implantation-processed wafer and adjust the wafer temperature to room temperature or a temperature close to room temperature.

At least one of the first temperature adjusting device 82a, the second temperature adjusting device 82b, and the third temperature adjusting device 90 may be the wafer temperature adjusting device 100 of FIG. 1. Accordingly, at least one of the first load lock chamber 66a, the second load lock chamber 66b, and the buffer chamber 70 may be the temperature adjusting chamber 98 of FIG. 1.

In an example of the wafer transport device 18 shown in FIG. 6, at least one of the first temperature adjusting device 82a and the second temperature adjusting device 82b is the wafer temperature adjusting device 100 of FIG. 1. Additionally, the third temperature adjusting device 90 is the wafer temperature adjusting device 100 of FIG. 1. In this case, the third temperature adjusting device 90 heats the wafer before the implantation process. At least one of the first temperature adjusting device 82a and the second temperature adjusting device 82b cools the implantation-processed high-temperature wafer to room temperature or a temperature close to room temperature.

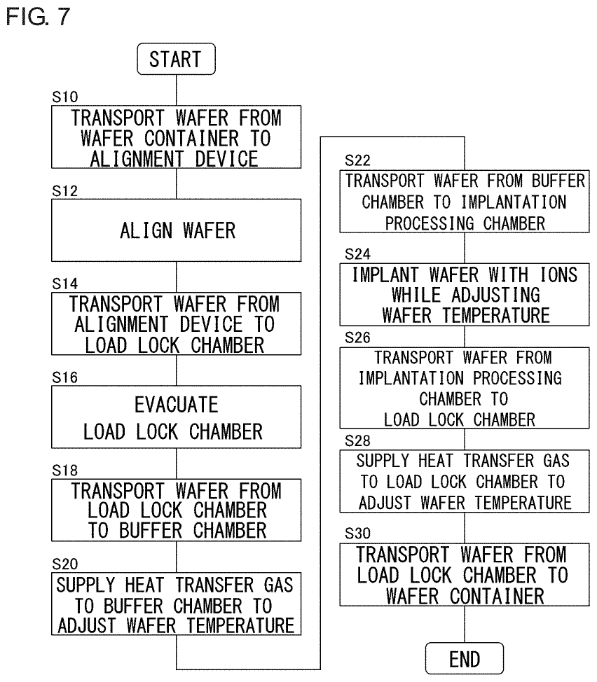

FIG. 7 is a flowchart showing an example of an operation of the wafer transport device 18. In FIG. 7, the detailed operations of the gates valve are omitted, and the transport of the wafer is mainly described. The first atmospheric transport mechanism 74a or the second atmospheric transport mechanism 74b transports the wafer stored in the wafer container 72 from the wafer container 72 to the alignment device 76 (S10). The alignment device 76 aligns the wafer (S12). The first atmospheric transport mechanism 74a or the second atmospheric transport mechanism 74b transports the wafer aligned by the alignment device 76 from the alignment device 76 to the first load lock chamber 66a or the second load lock chamber 66b (S14).

Next, the first load lock chamber 66a or the second load lock chamber 66b is sealed and evacuated (S16). When the evacuation is completed in the first load lock chamber 66a or the second load lock chamber 66b, the intermediate transport mechanism 84 transports the wafer from the first load lock chamber 66a or the second load lock chamber 66b to the buffer chamber 70 (S18). The buffer chamber 70 is sealed and the heat transfer gas is supplied into the buffer chamber 70. Then, the third temperature adjusting device 90 heats or cools the wafer loaded into the buffer chamber 70 and adjust the wafer temperature to a temperature suitable for the implantation process (S20). The pressure of the heat transfer gas supplied into the buffer chamber 70 may be lower than the atmospheric pressure and may be, for example, about 1 to 500 torr. After the temperature adjustment is completed in the buffer chamber 70, the buffer chamber 70 may be evacuated to exhaust the heat transfer gas. When the temperature adjustment is completed in the buffer chamber 70, the intermediate transport mechanism 84 transports the wafer from the buffer chamber 70 to the implantation processing chamber 16 (S22). The wafer holding device 52 heats or cools the wafer and adjusts the wafer temperature to a temperature suitable for the implantation process. While the wafer temperature is adjusted by the wafer holding device 52, the wafer is irradiated with the ion beam and the ion implantation process is performed (S24).

When the ion implantation process is completed, the intermediate transport mechanism 84 transports the implantation-processed wafer from the implantation processing chamber 16 to the first load lock chamber 66a or the second load lock chamber 66b (S26). Next, the wafer temperature is adjusted in the first load lock chamber 66a or the second load lock chamber 66b by sealing the first load lock chamber 66a or the second load lock chamber 66b to supply and by supplying the heat transfer gas (S28). The first temperature adjusting device 82a or the second temperature adjusting device 82b is, for example, the wafer temperature adjusting device 100 of FIG. 1, and adjusts the wafer temperature to room temperature or a temperature close to room temperature. By supplying the heat transfer gas having atmospheric pressure, the first temperature adjusting device 82a or the second temperature adjusting device 82b can complete the adjustment of the wafer temperature in a slight amount of time required for the first load lock chamber 66a or the second load lock chamber 66b to reach atmospheric pressure. When the temperature adjustment by the first temperature adjusting device 82a or the second temperature adjusting device 82b is completed, the first load lock chamber 66a or the second load lock chamber 66b is opened to the air atmosphere. After that, the first atmospheric transport mechanism 74a or the second atmospheric transport mechanism 74b transports the implantation-processed wafer from the first load lock chamber 66a or the second load lock chamber 66b to the wafer container 72 (S30).

According to the present embodiment, by providing the wafer temperature adjusting device in the load lock chambers 66a or 66b, the temperature of the wafer W can be adjusted by utilizing the time required to bring the load lock chambers 66a or 66b to atmospheric pressure. Accordingly, even in a case where the high-temperature implantation or the low-temperature implantation is performed, the time added for adjusting the wafer temperature can be minimized, and the productivity of the ion implanter 10 can be increased.

According to the present embodiment, since it is not necessary to hold the wafer W by utilizing an electrostatic chuck or the like, it is possible to suppress the back surface particles generated by rubbing the wafer W when bringing the wafer W into close contact with the stage or the like. As a result, it is possible to suppress degradation of device yield caused by the adhesion of the particles to the wafer W. Additionally, according to the present embodiment, it is possible to avoid the problem of temperature non-uniformity in the wafer surface which occurs in utilizing thermal radiation for heat the water. As a result, it is possible to suppress the degradation of device yield caused by non-uniform heating in the wafer surface.

In the processing flow of FIG. 7, a case where the wafer W before the implantation process is heated or cooled in the buffer chamber 70, and the implantation-processed wafer W is cooled or heated in the first load lock chamber 66a or the second load lock chamber 66b is shown. In a modification example, the wafer W before the implantation process may be heated or cooled in the buffer chamber 70, and the implantation-processed wafer W may be cooled or heated in the buffer chamber 70. In this case, the first load lock chamber 66a and the second load lock chamber 66b may not be used for heating or cooling the wafer W. In another modification example, the wafer W before the implantation process is heated or cooled in the first load lock chamber 66a or the second load lock chamber 66b, and the implantation-processed wafer W may be cooled or heated in the second load lock chamber 66b or the first load lock chamber 66a. For example, the wafer W before the implantation process may be heated or cooled in the first load lock chamber 66a, and the implantation-processed wafer W may be cooled or heated in the second load lock chamber 66b. In this case, the wafer transport device 18 may not include the buffer chamber 70.

The first load lock chamber 66a, the second load lock chamber 66b, or the buffer chamber 70 may include only one wafer temperature adjusting device or may include a plurality of wafer temperature adjusting devices. The first load lock chamber 66a, the second load lock chamber 66b, or the buffer chamber 70 may include, for example, two or more wafer temperature adjusting devices disposed in the vertical direction (y direction). Each of the two or more wafer temperature adjusting devices provided in the same chamber may be used for both heating and cooling of the wafer W, or may be used for only heating or cooling the wafer W. The first load lock chamber 66a, the second load lock chamber 66b, or the buffer chamber 70 may include, for example, a wafer temperature adjusting device dedicated to heating and a wafer temperature adjusting device dedicated to cooling.

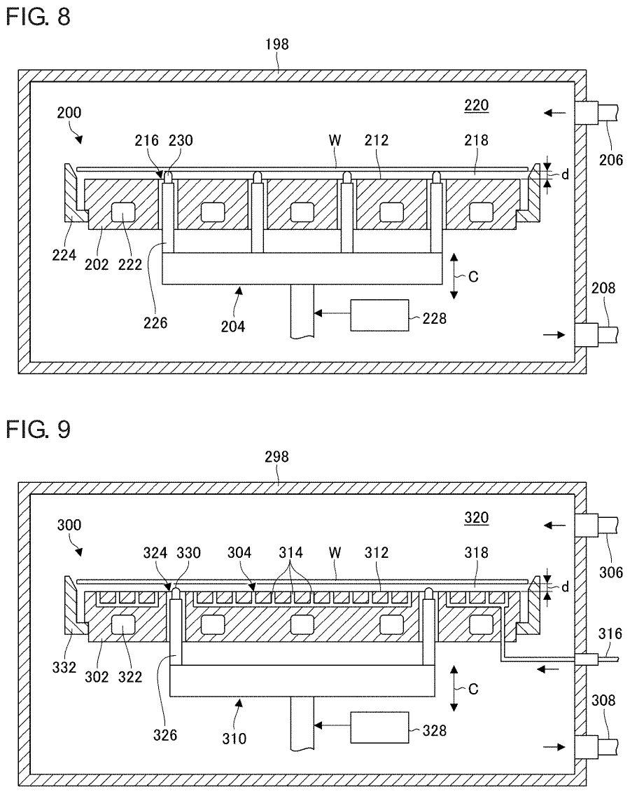

FIG. 8 is a sectional view showing a schematic configuration of a wafer temperature adjusting device 200 according to another embodiment. The wafer temperature adjusting device 200 is provided inside a temperature adjusting chamber 198. The wafer temperature adjusting device 200 includes a stage 202, a wafer support mechanism 204, a gas supply unit 206, and a gas exhaust unit 208. The gas supply unit 206 and the gas exhaust unit 208 are configured in the same manner as the gas supply unit 106 and the gas exhaust unit 108 in FIG. 1.

The stage 202 has an upper surface 212. The upper surface 212 includes a flat surface, and a plurality of protrusions are not formed thereon. The stage 202 is configured to adjust the temperature of the upper surface 212. The stage 202 has a flow path 222 through which a temperature adjusting fluid for adjusting the temperature of the upper surface 212 flows. The stage 202 may include a heater for temperature adjustment in addition to or instead of the flow path 222. Wafer guides 224 are provided at an outer periphery of the stage 202. The wafer guides 224 are configured in the same manner as the wafer guides 132 of FIG. 1, for example.

The wafer support mechanism 204 has a plurality of lift pins 226 and a drive mechanism 228 that drives the plurality of lift pins 226 in the vertical direction (direction of arrow C). The plurality of lift pins 226 are provided in through-holes 216 that penetrate the stage 202. A tip 230 of each of the plurality of lift pins 226 is made of quartz, PEEK, or the like. In a case where the temperature of the wafer W is adjusted, the wafer support mechanism 204 supports the wafer W in a state where the distance d between the wafer W and the upper surface 212 is maintained within the predetermined range. The wafer support mechanism 204 supports the wafer W in a state where a first space 218 between the wafer W and the upper surface 212 and a second space 220 above the wafer W communicate with each other. In a case where the wafer W is transported, the wafer support mechanism 204 makes the distance d between the wafer W and the upper surface 212 larger than the predetermined range so that the wafer handler can be inserted between the wafer W and the upper surface 212.

In the present embodiment, the plurality of lift pins 226 that supports the wafer W correspond to the plurality of protrusions 116 of FIG. 1. The plurality of lift pins 226 can be displaced in the vertical direction, and protruding height of each pin from the upper surface 212 to the tip 230 is variable. That is, the distance d between the wafer W and the upper surface 212 can be changed when the temperature of the wafer W is adjusted. The distance d between the wafer W and the upper surface 212 affects the heat transfer efficiency between the wafer W and the upper surface 212. For example, since the heat transfer efficiency is increased when the distance d is reduced, the time required for the temperature adjustment of the wafer W can be shortened. On the other hand, since the heat transfer efficiency is decreased when the distance d is increased, the time required for the temperature adjustment of the wafer W can be lengthened. For example, by increasing the distance d, the temperature of the wafer W can be slowly adjusted, and an excessive temperature change can be prevented from occurring.

FIG. 9 is a sectional view showing a schematic configuration of a wafer temperature adjusting device 300 according to still another embodiment. The wafer temperature adjusting device 300 is provided inside a temperature adjusting chamber 298. The wafer temperature adjusting device 300 includes a stage 302, a wafer support mechanism 304, a first gas supply unit 306, a gas exhaust unit 308, and a lift-up mechanism 310. The first gas supply unit 306, the gas exhaust unit 308, and the lift-up mechanism 310 are configured in the same manner as the gas supply unit 106, the gas exhaust unit 108, and the lift-up mechanism 110 in FIG. 1.

The stage 302 has an upper surface 312. The upper surface 312 includes a flat surface, and a plurality of protrusions are not formed thereon. The stage 302 is configured to adjust the temperature of the upper surface 312. The stage 302 has a flow path 322 through which a temperature adjusting fluid for adjusting the temperature of the upper surface 312 flows. The stage 302 may include a heater for temperature adjustment in addition to or instead of the flow path 322. Wafer guides 332 are provided at an outer periphery of the stage 302. The wafer guides 332 are configured in the same manner as the wafer guides 132 of FIG. 1.

The wafer support mechanism 304 has a plurality of gas supply ports 314 and a second gas supply unit 316. The plurality of gas supply ports 314 are provided in a two-dimensional array on the upper surface 312. The plurality of gas supply ports 314 are outlets for gas supplied from the second gas supply unit 316 and blow the gas toward the back surface of the wafer W disposed above the stage 302. The wafer W floats due to the gas pressure of the gas blown from the plurality of gas supply ports 314, and the distance d between the upper surface 312 and the wafer W is maintained within the predetermined range. Accordingly, the wafer support mechanism 304 supports the wafer W by the pressure of the gas blown onto the wafer W from the plurality of gas supply ports 314. The wafer support mechanism 304 supports the wafer W in a state where the first space 318 between the upper surface 312 and the wafer W and the second space 320 above the wafer W communicate with each other.

The gas supplied from the second gas supply unit 316 to the plurality of gas supply ports 314 may be the same as or different from the heat transfer gas supplied by the first gas supply unit 306. The gas supplied by the second gas supply unit 316 may be dry air, nitrogen gas, rare gas, or mixture thereof. The heat transfer gas supplied to the inside of the temperature adjusting chamber 298 may be supplied from both the first gas supply unit 306 and the second gas supply unit 316 or may be supplied only from the second gas supply unit 316. In addition, in a case where the second gas supply unit 316 supplies the heat transfer gas, the wafer temperature adjusting device 300 may not include the first gas supply unit 306.

The lift-up mechanism 310 includes a plurality of lift pins 326 and a drive mechanism 328 that drives the plurality of lift pins 326 in the vertical direction (direction of arrow C). Each of the plurality of lift pins 326 is provided in each of a plurality of through-holes 324 that penetrate the stage 302. A tip 330 of each lift pin 326 is made of quartz, PEEK, or the like. The lift-up mechanism 310 supports the wafer W in a case where the wafer W is not supported by the wafer support mechanism 304, that is, in a case where the wafer W does not float by the gas pressure. In a case where the wafer W is transported, the lift-up mechanism 310 makes the distance d between the wafer W and the upper surface 312 larger than the predetermined range so that the wafer handler can be inserted between the wafer W and the upper surface 312.

According to the present embodiment, the temperature of the wafer W can be more efficiently adjusted by blowing the gas onto the back surface of the wafer W. Additionally, by causing the wafer W to float with the gas pressure, contact area between the back surface of the wafer W and the wafer support mechanism 304 can be minimized in the step of adjusting the temperature of the wafer W. Accordingly, the generation of particles on the back surface of the wafer W can be further suppressed.

Although the present invention has been described above with reference to the above-described embodiments, the present invention is not limited to the above-described embodiments, and those obtained by appropriately combining or substituting the configurations of the respective embodiments are also included in the present invention. Additionally, it is also possible to appropriately rearrange the combination and the order of processing in the respective embodiments on the basis of the knowledge of those skilled in the art and to add modifications such as various design changes to the embodiments, and embodiments to which such modifications are added may also be included within the scope of the present invention.

It should be understood that the invention is not limited to the above-described embodiment, but may be modified into various forms on the basis of the spirit of the invention. Additionally, the modifications are included in the scope of the invention.

What is claimed is:

1. A wafer temperature adjusting device comprising:
an upper surface;
a wafer support mechanism that supports a wafer above the upper surface in a state where a distance between the upper surface and the wafer is maintained within a predetermined range and a first space between the upper surface and the wafer communicates with a second space above the wafer;
a stage that adjusts a temperature of the upper surface; and
a gas supply unit that supplies a heat transfer gas to the first space and the second space.

2. The wafer temperature adjusting device according to claim 1,
wherein the distance between the upper surface and the wafer is 0.1 μm or more and 1,000 μm or less.

3. The wafer temperature adjusting device according to claim 1,
wherein a pressure of the heat transfer gas is 1 torr or more.

4. The wafer temperature adjusting device according to claim 1,
wherein a pressure of the heat transfer gas is determined such that a mean free path in the heat transfer gas is smaller than the distance between the upper surface and the wafer.

5. The wafer temperature adjusting device according to claim 1,
wherein the wafer support mechanism includes a plurality of protrusions that protrude from the upper surface.

6. The wafer temperature adjusting device according to claim 5,
wherein sum of formation areas of the plurality of protrusions is 50% or less of a total area of the upper surface.

7. The wafer temperature adjusting device according to claim 5,
wherein the number of the plurality of protrusions is 0.01 or more and 10,000 or less per square centimeter of the upper surface.

8. The wafer temperature adjusting device according to claim 5,
wherein at least one of the plurality of protrusions is detachably attached to the upper surface or the stage.

9. The wafer temperature adjusting device according to claim 5, further comprising:
a support plate that includes the upper surface and the plurality of protrusions and is detachably attached to the stage.

10. The wafer temperature adjusting device according to claim 5,
wherein the upper surface and the plurality of protrusions are integrally formed on the stage.

11. The wafer temperature adjusting device according to claim 5,
wherein each of the plurality of protrusions has a protrusion height from the upper surface that is variable.

12. The wafer temperature adjusting device according to claim 5,
wherein the plurality of protrusions are made of a ceramic material.

13. The wafer temperature adjusting device according to claim 5,
wherein the plurality of protrusions are made of a resin material, and the stage is made of a ceramic material or a metal material.

14. The wafer temperature adjusting device according to claim 5, further comprising:
a lift pin that supports the wafer apart from the plurality of protrusions; and
a drive mechanism that drives the lift pin in a vertical direction.

15. The wafer temperature adjusting device according to claim 1,
wherein the wafer support mechanism includes a gas supply port for blowing gas from the upper surface toward the wafer to float the wafer by gas pressure.

16. The wafer temperature adjusting device according to claim 1, further comprising:
a flow path that is provided inside the stage and allows a temperature adjusting fluid for adjusting the temperature of the upper surface to flow therethrough.

17. A wafer processing apparatus comprising:
a vacuum processing chamber in which a process on the wafer is performed;
the wafer temperature adjusting device according to claim 1, which adjusts the temperature of the wafer in at least one of timings before and after the process in the vacuum processing chamber;
a temperature adjusting chamber where the wafer temperature adjusting device is provided;
a valve capable of sealing between the vacuum processing chamber and the temperature adjusting chamber; and
an evacuation system that reduces a pressure in the temperature adjusting chamber.

18. The wafer processing apparatus according to claim 17, further comprising:
an intermediate transfer chamber that is provided between the vacuum processing chamber and the temperature adjusting chamber,
wherein the valve is provided between the intermediate transfer chamber and the temperature adjusting chamber.

19. The wafer processing apparatus according to claim 17,
wherein the temperature adjusting chamber is a load lock chamber for loading the wafer into the vacuum processing chamber and unloading the wafer from the vacuum processing chamber, and
the wafer processing apparatus further comprises another valve capable of sealing between the load lock chamber and an air atmosphere.

20. A wafer temperature adjusting method comprising:
adjusting a temperature of an upper surface;
supporting a wafer above the upper surface in a state where a distance between the upper surface and the wafer is maintained within a predetermined range and a first space between the upper surface and the wafer communicates with a second space above the wafer; and
supplying a heat transfer gas to the first space and the second space.
